(19) United States
(12) Patent Application Publication
(10) Pub. No.: US 2026/0358722 A1
(43) Pub. Date: Nov. 12, 2026

(54) APPARATUS FOR AND METHOD OF COMBINED DISPLAY OF OPTICAL MEASUREMENT INFORMATION

(71) Applicant: ASML Netherlands B.V., Veldhoven (NL)

(72) Inventors: Simon Reinald HUISMAN, Eindhoven (NL); Sebastianus Adrianus GOORDEN, Eindhoven (NL)

(73) Assignee: ASML Netherlands B.V., Veldhoven (NL)

(21) Appl. No.: 19/131,730

(22) PCT Filed: Nov. 3, 2023
(86) PCT No.: PCT/EP2023/080728

§ 371 Date: May 21, 2025

Related U.S. Application Data
(60) Provisional application No. 63/428,762, filed on Nov. 30, 2022.

(51) Int. Cl. G03F 7/00; G03F 9/00

(52) U.S. Cl. CPC G03F 7/70566; G03F 7/70633; G03F 7/706851; G03F 9/7003

(57) ABSTRACT

Disclosed is an apparatus for and method of simultaneous capture and presentation of multiple types of alignment information in which a pupil is divided and the radiation from the pupil is spatially separated. In some versions the alignment information is first order diffraction information and polarization channel intensity information which are presented simultaneously in an image-based system.

### CROSS-REFERENCE TO RELATED APPLICATIONS

This application claims priority of U.S. application 63/428,762 which was filed on 30. Nov. 2022, and which is incorporated herein in its entirety by reference.

### FIELD

The present disclosed subject matter relates to apparatus for and methods of obtaining and displaying measurement information in a lithographic apparatus and process.

### BACKGROUND

A lithographic apparatus applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g. part of a die, one die, or several dies) on a substrate (e.g. a silicon wafer).

Pattern transfer is typically accomplished by imaging onto a layer of radiation-sensitive material (resist) provided on the substrate. In general, a single substrate will contain a network of adjacent target portions that are successively patterned.

ICs are built up layer by layer, and modern ICs can have many layers. Successive layers or multiple processes on the same layer must be accurately aligned to the previous layer. Otherwise, electrical contact between structures will be poor and the resulting devices will not perform to specification. On Product Overlay (OPO) is a measure of a system's ability to print these layers accurately on top of each other. Good overlay improves device yield and enables smaller product patterns to be printed.

One or more patterns such as overlay marks are generally provided on the substrate to control the lithographic process to place device features accurately on the substrate. Different types of marks and different types of systems are known from different times and different manufacturers. Types of overlay marks include bidirectional fine (BF) wafer overlay marks and smaller format marks such as micro diffraction based overlay (uDBO) overlay marks (e.g., C16 or C10 marks). These marks are configured as patterns of, for example, lines.

Typically, these marks are printed one atop the other, i.e., one mark is printed on one layer and later a second mark is printed on another layer at a targeted position with respect to the first mark, i.e., above the first mark. If the two marks are in perfect registration, then the overlay error is zero and features on the second layer may be assumed to have been printed at the proper position. If the two marks are not in perfect registration, then there is a nonzero overlay error that indicates a degree of misalignment between the two layers. The lack of registration is encoded in the intensity of diffraction orders in an interference pattern of light scattered off the stacked overlay marks.

In particular, one type of alignment tool is a scatterometer in which a beam of radiation is directed onto a target on the surface of the substrate and properties of the scattered or reflected beam are measured. By comparing the properties of the beam before and after it has interacted with, e.g. been reflected or scattered by, the substrate, the properties of the substrate can be determined. This can be accomplished, for example, by comparing the reflected beam with data stored in a database of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

In angle resolved scatterometry, an illumination branch irradiates the overlay target over a large band of incidence space. Diffraction orders of the light from the grating are then captured. The zero order intensity varies symmetrically as a function of overlay whereas the +/−1 order intensities vary asymmetrically as a function of overlay. Overlay can be determined using the difference of intensity of the first orders.

The properties measured by the scatterometer for different wavelengths and angles may include the relative intensity of differently polarized radiation. These relative intensities may be used to correct for deformed marks caused by, e.g., asymmetry.

Lithographic apparatus are known to use multiple alignment systems to align the substrate with respect to the lithographic apparatus. The data can for example be obtained with any type of alignment sensor, for example a SMASH (SMart Alignment Sensor Hybrid) sensor, as described in U.S. Pat. No. 6,961,116, issued Nov. 1, 2005 and titled “Lithographic Apparatus, Device Manufacturing Method, and Device Manufactured Thereby” that employs a self-referencing interferometer with a single detector and four different wavelengths, and extracts the alignment signal in software. Another system is ATHENA (Advanced Technology using High order ENhancement of Alignment), as described in U.S. Pat. No. 6,297,876, issued Oct. 2, 2001, and titled “Lithographic Projection Apparatus with an Alignment System for Aligning Substrate on Mask,” which directs each of seven diffraction orders to a dedicated detector, or the ORION sensor which uses multiple polarizations per available signal (color).

All patent applications, patents, and printed publications cited herein are incorporated herein by reference in their entireties, except for any definitions, subject matter disclaimers or disavowals, and except to the extent that the incorporated material is inconsistent with the express disclosure herein, in which case the language in this disclosure controls.

Another known alignment system is described in WIPO International Pub. No. WO 2020/057900, published Mar. 26, 2020, and titled “Metrology Sensor for Position Metrology.” One of the systems described there uses a plurality of spatially incoherent illumination beams and multiple pupil points in an illumination pupil of the metrology device.

For the benefit of improving throughput there is a need for making alignment information available in a manner that facilitates and expedites measurement. This need can be addressed at least in part by displaying multiple types of data in parallel, i.e., at the same time. In a camera-based system it would thus be beneficial for some applications to be able to display simultaneously, for example, images conveying polarization-resolved measurements and intensity information per diffracted order. The need for the presently disclosed subject matter arises in this context.

### SUMMARY

The following presents a concise summary of one or more embodiments in order to provide a basic understanding of the present invention. This summary is not intended as an extensive overview of all contemplated embodiments or to identify key or critical elements of all possible embodiments nor delineate the scope of any or all possible embodiments. Its sole purpose is to present some concepts relating to one or more embodiments in a succinct form as a prelude to the more detailed description that is presented later.

In accordance with one aspect of an embodiment, there is disclosed a metrology device configured to collect radiation that has interacted with a pattern on a substrate, the metrology device comprising an objective arranged to gather the radiation and an optical module arranged to receive at least some of the radiation and adapted to split the radiation into first path radiation travelling in a first arm and second path radiation travelling in a second arm. One of the first arm and the second arm may comprise a polarization component adapted to rotate a polarization of a corresponding one of the first path radiation and the polarization intensity information, and the second arm may comprise a second arm component adapted to spatially separate the second path radiation.

The optical module further includes a polarizing beam splitter arranged to receive the first path from the first arm and the second path radiation from the second arm and to split the first path radiation into first channel first path radiation and second channel first path radiation and split the separated second path into first channel second path radiation and second channel second path radiation and to cause the first channel first path radiation and the first channel second path radiation to co-propagate as combined first channel radiation and to cause the second channel first path radiation and the second channel second path radiation to co-propagate as combined second channel radiation.

The metrology device may be an alignment sensor or part of an alignment sensing system. The metrology device may be an overlay sensor or part of an overlay sensing system. The second arm component adapted to spatially separate the second path radiation may be configurable. The second arm component adapted to spatially separate the second path radiation may comprise a rotatable wedge.

The metrology device may further comprise a first lens arranged to receive and focus the first channel radiation, a first array detector arranged at a focal plane of the first lens, a second lens arranged to receive and focus the second channel radiation, and a second array detector arranged at a focal plane of the second lens. The first array detector may comprise a first camera and the second array detector may comprise a second camera. The first array detector may have a first optical axis may be rotatable with respect to the first optical axis to improve filling of the first channel radiation on the first array detector. The polarization component may comprise a half-wave plate. The first arm may the arm that includes the polarization component adapted to rotate a polarization of the image information radiation. The polarization component may comprise a half-wave plate.

The second arm component may comprise a segmented optical wedge arranged to spatially separate the second path radiation. The segmented optical wedge may be transmissive. The segmented optical wedge may be reflective. The second arm component may comprise a partitioned aperture wavefront (PAW) imaging lens.

According to another aspect of an embodiment there is disclosed a metrology device configured to collect radiation that has interacted with a pattern on a substrate, the metrology device comprising an objective arranged to gather the radiation, and an optical module arranged to receive the at least some of the radiation and adapted to split the radiation into image information radiation travelling in a first arm and a second path radiation travelling in a second arm.

The first arm includes a half-wave plate adapted to rotate a polarization of the image information radiation, and the second arm includes a segmented optical wedge arranged to spatially separate the second path radiation. The optical module further includes a polarizing beam splitter arranged to receive the image information from the first arm and the second path radiation from the second arm and to split the image information radiation into first channel image information radiation and a second channel image information radiation and split the separated second path radiation into first channel second path radiation and a second channel second path radiation and to cause the first channel image information radiation and the first channel second path radiation to co-propagate as combined first channel radiation and to cause the second channel image information radiation and the second channel second path radiation to co-propagate as combined second channel radiation.

The device also includes a first lens arranged to receive and focus the first channel radiation, a first array detector arranged at a focal plane of the first lens, a second lens arranged to receive and focus the second channel radiation, and a second array detector arranged at a focal plane of the second lens.

The metrology device may be an alignment sensor or part of an alignment sensing system. The metrology device may be an overlay sensor or part of an overlay sensing system.

The first array detector may comprise a first camera and the second array detector may comprise a second camera. The first array detector may have a first optical axis and wherein the first array detector may be rotatable with respect to the first optical axis to improve filling of the first channel radiation on the first array detector. The segmented optical wedge may be rotatable.

According to another aspect of an embodiment there is disclosed an optical module comprising a first arm comprising a half-wave plate, a second arm comprising a segmented optical wedge, a neutral beam splitter arranged to split a beam of incoming radiation into a first part travelling in the first arm and a second part travelling in the second arm, a polarizing beam splitter arranged to receive the first part after the first part may have travelled the first arm and the second part after the second part may have travelled the second arm.

The half-wave plate may rotate a polarization of the first part by ninety degrees. The segmented optical wedge may separate the second part into a plurality of spatially separated components. The polarizing beam splitter may cause a first portion of the first part to co-propagate with a first portion of the second part. The polarizing beam splitter may cause a second portion of the first part to co-propagate with a second portion of the second part.

The optical module may be an alignment sensor or part of an alignment sensing system. The optical module may be an overlay sensor or part of an overlay sensing system. The segmented optical wedge may be rotatable.

According to another aspect of an embodiment there is disclosed an optical module comprising a first optical component comprising a neutral beam splitter arranged to split a beam of incoming radiation into a first part travelling in a first arm and a second part travelling in a second arm, the first arm comprising a second optical component comprising a half-wave plate, and the second arm comprising a third optical component comprising a segmented optical wedge, and a fourth optical component comprising a polarizing beam splitter arranged to receive the first part after the first part may have travelled the first arm and the second part after the second part may have travelled the second arm. The optical module further comprises a first transparent element attached to and connecting the first optical component and the second optical component, a second transparent element attached to and connecting the second optical component and the fourth optical component, a third transparent element attached to and connecting the first optical component and the third optical component, and a fourth transparent element attached to and connecting the third optical component and the fourth optical component, such that the optical module may be configured as a monolithic block.

The half-wave plate may rotate a polarization of the first part by ninety degrees. The segmented optical wedge may separate the second part into a plurality of spatially separated components. The polarizing beam splitter may cause a first portion of the first part to co-propagate with a first portion of the second part. The polarizing beam splitter may cause a second portion of the first part to co-propagate with a second portion of the second part.

The optical module may be an alignment sensor or part of an alignment sensing system. The optical module may be an overlay sensor or part of an overlay sensing system. The segmented optical wedge may be rotatable.

According to another aspect of an embodiment there is disclosed a metrology method comprising gathering radiation that has interacted with a pattern on a substrate, splitting at least part of the radiation into image information radiation and second path radiation, rotating a polarization of one of the second path and the image information radiation, and the second arm comprising second arm component adapted to spatially separate the second path radiation, and splitting the image information radiation into first channel image information radiation and second channel image information radiation and concurrently splitting the separated second path into first channel second path radiation and second channel second path radiation and to cause the first channel image information radiation and the first channel second path radiation to co-propagate as combined first channel radiation and to cause the second channel image information radiation and the second channel second path radiation to co-propagate as combined second channel radiation.

The metrology method may further comprise focusing the first channel radiation on a first array detector and focusing the second channel radiation on a second array detector.

Further embodiments, features, and advantages of the subject matter of the present disclosure, as well as the structure and operation of the various embodiments, are described in detail below with reference to accompanying drawings.

### BRIEF DESCRIPTION OF THE DRAWING

FIG. 1 shows a schematic, not to scale, view of an overall broad conception of a photolithography system.

FIG. 2A is an example of an overlay mark such as may be used in accordance with aspects of some embodiments.

FIG. 2B is an image of a diffraction order such as might be generated by interaction of the overlay mark of FIG. 2A with an incident beam.

FIG. 3A is a pupil representation corresponding to the resulting radiation following scattering of an off-axis illumination beam.

FIG. 3B shows the resultant pupil (captured orders only) resultant from four off axis beams.

FIG. 4 is a diagram of a system for simultaneous display of diffraction patterns and polarization channel intensity information in accordance with an aspect of an embodiment.

FIG. 5A is a representation of an example of a simultaneous display such as might be produced by the system of FIG. 4.

FIG. 5B is a diagram of a relative angular orientation of a spot mirror and a segmented optical wedge in a system such as that shown in FIG. 4.

FIG. 6A is a diagram of another system for simultaneous display of diffraction patterns and polarization channel intensity information in accordance with another aspect of an embodiment.

FIG. 6B is a diagram of another system for simultaneous display of diffraction patterns and polarization channel intensity information in accordance with another aspect of an embodiment.

FIG. 6C is a diagram of another system for simultaneous display of diffraction patterns and polarization channel intensity information in accordance with another aspect of an embodiment.

FIG. 7 is a diagram of another system for simultaneous display of diffraction patterns and polarization channel intensity information in accordance with another aspect of an embodiment.

FIG. 8A is a perspective view of an example of a segmented optical wedge such as might be used in various embodiments.

FIG. 8B is a perspective view of an example of a segmented lens array such as might be used in various embodiments.

FIG. 9 is a graphical representation of an arrangement of fields in a combined display in accordance with an aspect of an embodiment.

FIG. 10 is a graphical representation of an arrangement of fields in a combined display in accordance with an aspect of an embodiment.

FIG. 11 is a graphical representation of an arrangement of fields in a combined display in accordance with an aspect of an embodiment.

FIG. 12 is a diagram of a system for simultaneous display of diffraction patterns and polarization channel intensity information in accordance with an aspect of an embodiment.

FIGS. 13A, 13B, and 13C are diagrams of a portion of a system for simultaneous display of diffraction patterns and polarization channel intensity information in accordance with an aspect of an embodiment.

FIG. 14 is a diagram of a portion of a system for simultaneous display of diffraction patterns and polarization channel intensity information in accordance with an aspect of an embodiment.

FIG. 15 is a diagram of a portion of a system for simultaneous display of diffraction patterns and polarization channel intensity information in accordance with an aspect of an embodiment.

Further features and advantages of the disclosed subject matter, as well as the structure and operation of various embodiments of the disclosed subject matter, are described in detail below with reference to the accompanying drawings. It is noted that the applicability of the disclosed subject matter is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be implemented or practiced without adopting the specific design details described below. In other instances, well-known structures and devices are shown in block diagram form in order to facilitate description of one or more embodiments.

Embodiments of the present invention may be implemented in hardware, firmware, software, or any combination thereof. Embodiments of the present invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM), random access memory (RAM), magnetic disk storage media, optical storage media, flash memory devices, electrical, optical, acoustical, or other forms of propagated signals (e.g., carrier waves, infrared signals, digital signals, etc.), and others.

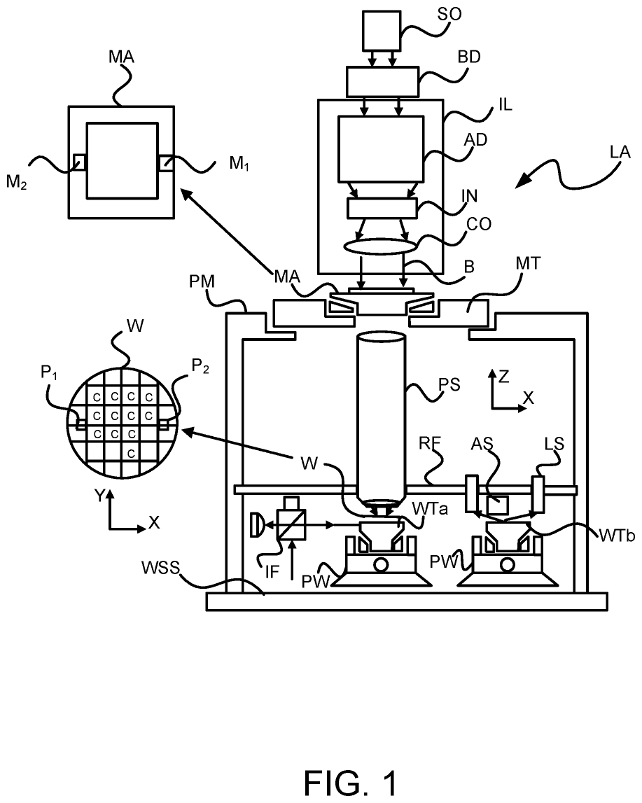

As an introduction, FIG. 1 schematically depicts an embodiment of a lithographic apparatus LA that may be associated with the present systems. The lithographic apparatus LA comprises an illumination system (illuminator) IL configured to condition a radiation beam B. The terms “radiation” and “beam” used herein encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

The lithographic apparatus LA also comprises a support structure (e.g. a mask table) MT constructed to support a patterning device (e.g. a mask) MA and connected to a first positioner PM configured to accurately position the patterning device in accordance with certain parameters; one or more substrate tables (e.g. a wafer table) WT (in the example, two wafer tables, WTa and WTb) configured to hold a substrate (e.g. a resist-coated wafer) W. Each wafer table is mechanically coupled to a respective positioner PW configured to accurately position the substrate on a wafer support surface WSS in accordance with certain parameters.

The lithographic apparatus LA also comprises a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF.

As depicted, the apparatus is of a transmissive type (e.g. employing a transmissive mask). Alternatively, the apparatus may be of a reflective type (e.g. employing a programmable mirror array of a type as referred to above or employing a reflective mask).

The illuminator IL receives a beam of radiation from a radiation source SO. The source and the lithographic apparatus may be separate entities, for example when the source is an excimer laser. In such cases, the radiation beam is passed from the source SO to the illuminator IL with the aid of a beam delivery system BD comprising, for example, suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system. If the radiation source is of the type that produces EUV radiation then generally reflective optics will be used.

The illuminator IL may comprise an adjuster AD configured to adjust the (angular / spatial) intensity distribution of the beam. In addition, the illuminator IL generally comprises various other components, such as an integrator IN and a condenser CO. The illumination system may include various types of optical components for directing, shaping, or controlling radiation. Thus, the illuminator IL provides a conditioned beam of radiation B, having a desired uniformity and intensity distribution in its cross section.

The support structure MT supports the patterning device using mechanical, vacuum, electrostatic or other clamping techniques to hold the patterning device. The term “patterning device” used herein should be broadly interpreted as referring to any device that can be used to impart a pattern in a target portion of the substrate. A patterning device may be transmissive or reflective. Examples of patterning devices include masks, programmable mirror arrays, and programmable LCD panels.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate.

In operation of the lithographic apparatus LA, the radiation beam B is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the patterned radiation beam B passes through the projection system PS, which focuses the beam onto a target portion C of the substrate W. With the aid of its respective positioner PW and position sensor IF (e.g. an interferometric device, linear encoder, 2-D encoder or capacitive sensor), the wafer table WTa or WTb can be moved accurately, e.g. to position different target portions C in the path of the patterned radiation beam B. Similarly, another positioner and another position sensor (which are not explicitly depicted in FIG. 1) can be used to accurately position the patterning device MA with respect to the path of the radiation beam B, e.g. after mechanical retrieval from a mask library, or during a scan.

Patterning device MA and substrate W may be aligned using patterning device marks M1, M2 and marks P1, P2. Although the marks as illustrated occupy dedicated target portions, they may be located in spaces between target portions. Similarly, in situations in which more than one die is provided on the patterning device MA, the patterning device marks may be located between the dies.

The substrate referred to herein may be processed, before or after exposure, for example in a track (a tool that typically applies a layer of resist to a substrate and develops the exposed resist) or a metrology or inspection tool. Where apposite, the disclosure herein may be applied to such and other substrate processing tools. Further, the substrate may be processed more than once, for example in order to create a multi-layer IC, so that the term “substrate” as used herein may also refer to a substrate that already includes one or more processed layers.

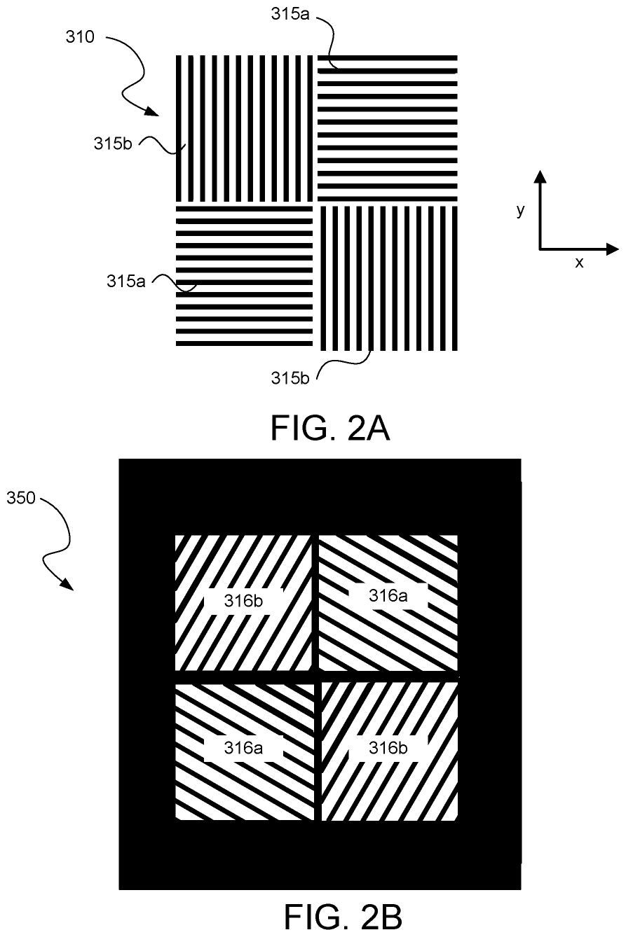

FIGS. 2A and 2B show some aspects of an example of alignment marks for determining alignment parameters. FIG. 2A illustrates a target 310 which is an example of a uDBO overlay mark that can be used as an overlay mark in some embodiments. The target 310 comprises four sub-targets, comprising two gratings (periodic structures) 315a extending in a first direction (x-direction) and two gratings 315b extending in a second, perpendicular direction (y-direction). The pitch of the gratings may be in the range, for example, of 300-800 nm.

In a manner similar to other metrology devices usable for alignment sensing, a shift in the target grating position causes a phase shift between diffracted orders, such as, the +1 and −1 diffracted orders, per direction. The diffraction orders are caused to interfere on a camera. The phase shift between the diffracted orders results in a corresponding shift of the interference fringes on the camera. It is thus possible to determine the alignment position from the position of the interference fringes on the camera.

Specifically, the captured orders in this example include the −1 x direction diffraction order, the +1 x direction diffraction order, the −1 y direction diffraction order, and the +1 y direction diffraction order. These diffraction orders are imaged on a camera where they interfere forming a fringe pattern 350, such as shown in FIG. 2B, with fields 316a and 316b, corresponding respectively to gratings 315a and 315b. In the example shown, the fringe patterns are diagonal because the diffracted orders are diagonally arranged in the pupil, although other arrangements are possible with a different resulting different fringe pattern orientation.

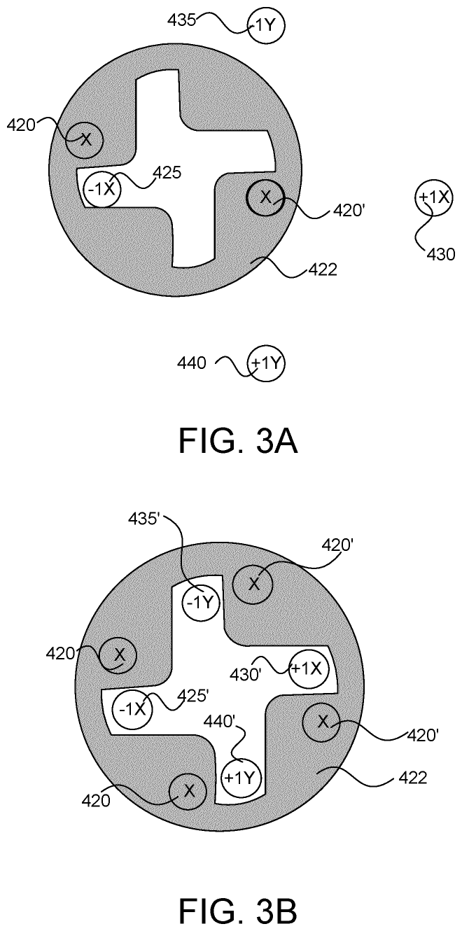

FIGS. 3A and 3B illustrate the working principle of the metrology system. FIG. 3A is a pupil representation corresponding to the resulting radiation following scattering of a single off-axis illumination beam 420. The 0^{th} order diffracted beam is shown as 420′. The shaded region 422 corresponds to the blocking (i.e., reflecting or absorbing) region of a specific spot mirror design, with white representing the transmitting region, as may be used in an embodiment. Such a spot mirror design is merely one example of a pupil block which ensures that undesired light (e.g., zeroth orders and light surrounding the zeroth orders) is not detected. Other spot mirror profiles (or zero order blocks generally) can be used. As used herein, the term “spot mirror” refers to any optical element used for zero order blocking.

As can be seen in FIG. 3A, only one of the higher diffraction orders is captured, more specifically the −1 X direction diffraction order 425. The +1 X direction diffraction order 430, the −1 Y direction diffraction order 435 and the +1 Y direction diffraction order 440 fall outside of the pupil (detection NA represented by the extent of spot mirror 422) and are not captured. Any higher orders (not illustrated) also fall outside the detection NA. The zeroth order 420 is shown for illustration but will actually be blocked by the spot mirror or zero order block 422.

FIG. 3B shows the resultant pupil (captured orders only) resultant from four off axis beams. The captured orders include the −1 X direction diffraction order 425′, a +1 X direction diffraction order 430′, a −1 Y direction diffraction order 435′ and a +1 Y direction diffraction order 440′. These diffraction orders are imaged on the camera where they interfere forming the fringe patterns shown in FIG. 2B. Again, in the example shown, the fringe pattern is diagonal as the diffracted orders are diagonally arranged in the pupil, although other arrangements are possible with a different resulting fringe pattern orientation. The original off-axis illumination beams 420 are at least partially coherent for the x-illumination orders and at least partially coherent for the y-illumination orders to permit the corresponding diffracted orders to interfere.

As mentioned, it is desirable for some applications to have the ability to present multiple images in a coordinated, consolidated format, each image conveying its own alignment data, e.g., images that represent information related to a selection of diffracted orders for a particular polarization of radiation that has interacted with a pattern. In accordance with an aspect of an embodiment this is accomplished by the use of a system that can be implemented as a compact optical building block without the need of switchable optical elements.

According to an aspect of an embodiment, an optical arrangement includes at least two paths for radiation that has interacted with a pattern on a substrate. The first path conveys a first portion of the radiation (first path radiation) and the second path conveys a second portion of the radiation (second path radiation). The first path and the second path contain different optical elements so that the first path creates a first image including first image information and the second path creates a second image including second image information. The images may then be co-presented for simultaneous composite display of the first image and the second image.

As examples, the first image may be an interference image and the second image may be an intensity image. As another example, in the case in which the second path includes optics that crop a portion of the pupil and image the cropped radiation, the first image may be characterized as a full image and the second image may be characterized as a partial pupil image. As another example, the first path may create a conventional bright-field image and the other path may convey a “dark-field imaging mode” image. In such an embodiment a partial pupil block may be placed along with an image separation element (e.g., a wedge or tilted mirror or tilted beam splitter) to separate the images in the composite image. As another example, one of the paths could implement a “phase contrast imaging mode.” Such an arrangement would use a phase plate in part of the pupil that shifts the phase in the part of the pupil with respect to the rest of the pupil. As yet another example, there may be an arrangement in which a focused image comes from one path and a defocused image comes from the other path. This could be achieved by, for example, adding a weak lens in the second path. Such an arrangement would essentially enable retrieving both the phase and amplitude of the light from a single image if spatially coherent light is used.

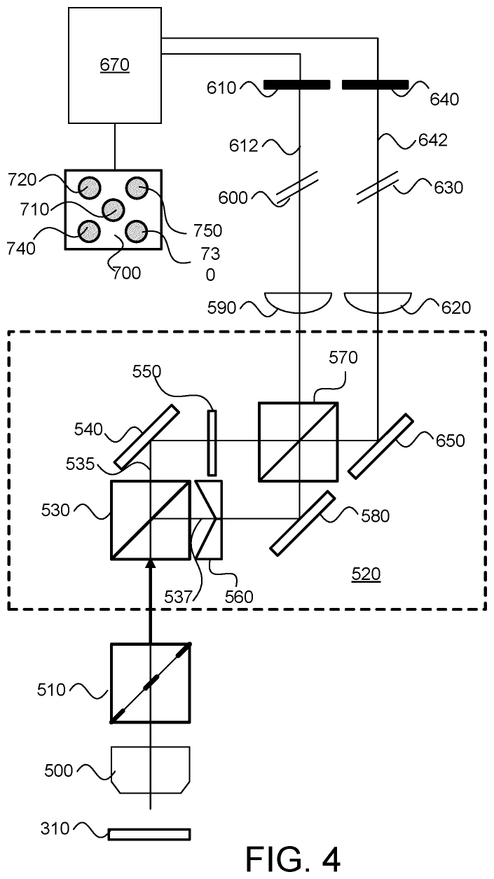

Specifically, in an embodiment diagrammed in FIG. 4, an objective 500 receives radiation that has interacted with a pattern, e.g., an overlay mark such as overlay mark 310 as described above. The radiation from the objective 500 passes through a spot mirror 510 which partially blocks radiation that is not used for metrology such as the zeroth order. The radiation then passes into a module 520 at the objective pupil plane.

The incident pupil is split by a non-polarizing beam splitter (NPBS) 530 into two arms, a first arm 535 and a second arm 537. This incident pupil will contain certain polarization state information collected from target 310. The system presents information related to the alignment response for the target 310 when the incident pupil is projected on an orthogonal polarization basis, e.g. X polarized and Y polarized. The first arm 535 transmits a first light bundle to an optical element 550 that rotates its polarization by 90 degrees, such as a half-wave plate (HWP). The second arm 537 uses a second arm component 560 to realize spatial separation of the images in the lower light bundle. The second arm component 560 may be an optical wedge or a partitioned aperture wavefront (PAW) imaging lens as described below. Spatial separation in this context means that second arm component 560 gives a controlled angle to each pupil segment, causing each pupil segment to be focused at a different location in the plane at a first array detector 610 and a second array detector 640. Each pupil segment can contain an individual diffracted order, or a selection of diffracted orders. In some embodiments the second arm component 560 is configurable. For example, in the case where the second arm component 560 is realized as an optical wedge, the optical wedge may be rotatable.

Both of the first and second arms 535 and 537 are combined on a polarizing beam splitter (PBS) 570 or its optical equivalent allowing for polarization resolved measurements. The PBS 570 projects the original object polarization in the second arm 537 to a defined orthogonal polarization basis, such as X or Y. In other words, the first arm radiation and the second arm radiation combine at PBS 570 which then divides the incident radiation into two channels, in this example, two polarization resolved channels, with each channel having first arm radiation and second arm radiation. Mirrors 540 and 580 are optionally supplied to fold the beam paths as desired to permit a physically compact configuration. One projected polarization state channel propagates through a lens 590 and optional folding optics 600 to a first array detector 610. The other orthogonal projected polarization state channel has its path folded by folding mirror 650 to propagate through a lens 620 and optional folding optics 630 to a second array detector 640. Here and elsewhere, the term “array detector” has its broadest sense of any device or system capable of capturing a light distribution including a one dimensional array detector, a two dimensional array detector, e.g., a camera, and a CCD or CMOS sensor. In the example shown, the array detectors 610 and 640 are cameras. Either first array detector 610 or second array detector 640, or both, may be rotated around its optical axis 612 and 642, respectively, to improve the extent to which the images fill the array detector sensor.

The signals from the array detectors 610, 640 are provided to a processing unit 670 which processes the signals in a known way to generate a combined display 700 that simultaneously displays fields 710, 720, 730, 740, and 750 which together include information from both channels. As described more fully below, the arrangement and selection of optical components can be chosen to obtain any one of a number of relative positionings of these fields in the combined display 700.

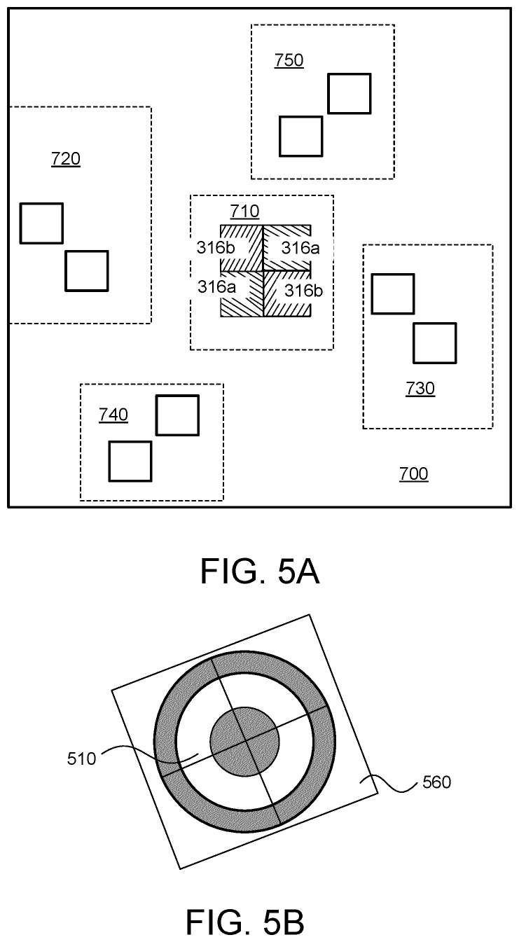

The combined outputs may result in camera pictures including multiple fields. An example of such a combined display of results is shown in FIG. 5A as combined display 700. The central field 710 corresponds to the collection of fringe patterns 350 from FIG. 2B. The surrounding fields 720, 730, 740, and 750 include pictures with individual polarization intensity information. In other words, the diffraction pattern and the intensity patterns of the same polarization-projected state are imaged on the same array detector. Specifically, field 720 includes the intensity information for target fields for one diffracted first order (e.g., −1^{st} X order) for the polarization channel being displayed. Field 730 includes the intensity information for target fields for another diffracted order (e.g., +1st X order) for the polarization channel being displayed. Field 740 includes the intensity information for target fields for another diffracted first order (e.g., −1st Y order) for the polarization channel being displayed. Field 750 includes the intensity information for target fields for another diffracted order (e.g., +1st Y order) for the polarization channel being displayed.

The orientation, arrangement, and content of the fields depends on the wedge orientation and design. Here, “content” refers to which diffraction orders are imaged at which positions on the displayed combination image. In the embodiment shown the second arm component 560 is a four-fold wedge oriented with respect to a spot mirror 510 as indicated in FIG. 5B. It will be understood, however, that other relative orientations and a different number of wedge segments may be used. The concepts elucidated herein may be extended to a different number and/or orientation and/or shape of segments, for example to separate higher orders.

In this embodiment the path defined by objects NPBS 530—mirror 540—HWP 550—PBS 570 is traversed by radiation forming the alignment pattern. The path defined by NPBS 530—wedge 560—mirror 580—PBS 570 is traversed by radiation forming the surrounding fields, each representing a selection of diffracted orders. Because both image paths get recombined on the PBS 570, the transmitted output has orthogonal polarizations. The system is configured to permit analysis of the polarization state of the radiation as it arrives at NPBS 530 by projecting the radiation on a desired polarization basis. This means that for a particular polarization state at NPBS 530, both resulting image paths corresponding to this particular polarization state are routed to the same focal plane. This is enabled by the introduction of HWP 550, which rotates the polarization state of the image by 90°.

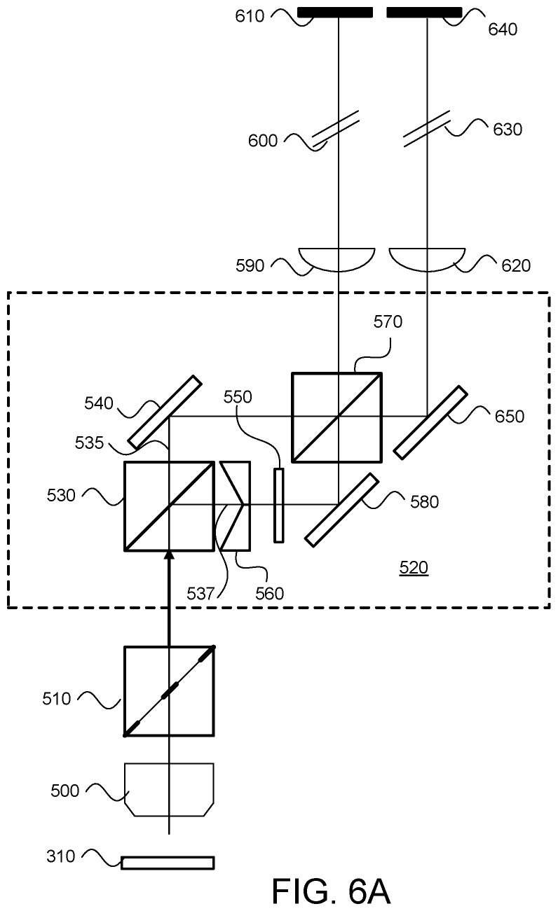

Instead of rotating the polarization state using HWP 550 placed in the image path NPBS 530—mirror 540—HWP 550—PBS 570, the polarization rotation could also be effected by placing an HWP in the path forming the image of surrounding structures NPBS 530—wedge 560—mirror 580—PBS 570. This is shown in FIG. 6A in which the HWP 550 is in the second arm 537. In another embodiment the wedge, in addition to the particular wedge geometry adapted to change the direction of the beams in each pupil segment, is made of a material that rotates the polarization, thus obviating the need for a separate element to perform this function. This is shown in FIG. 6B in which the wedge 560′ functions both as an optical wedge as well as a polarization rotating element.

For embodiments in which dispersion is exploited, the function of the wedge could be performed, for example, with a grating, resulting in a deflection angle exhibiting a strong dependence on wavelength. This is shown in FIG. 6C, in which the second arm component 560 of the embodiment of FIG. 6A is realized as a deflection element 565 which may be a grating or any other element which spatially separates the radiation passing through it.

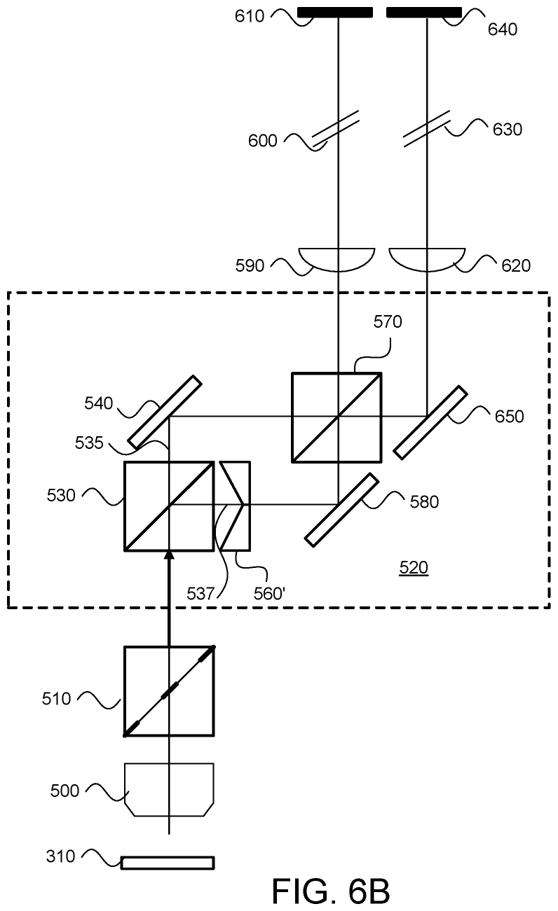

In accordance with another aspect of an embodiment, one potential advantage of the embodiments just described is that the components may be fabricated as a monolithic block with pieces of a transparent material such as glass affixed to one another using, e.g., an adhesive. An example of such an arrangement is shown in FIG. 7. Module 522 is made up of the optical components of the embodiment of FIG. 4 adhered to transparent pieces 541, 551, 561, 571, and 581. Alternatively, there may be air gaps in at least part of the optical paths between the individual optical components. The use of such air gaps may be exploited to minimize the optical path length.

Simultaneous access to polarization channels and intensity information has the potential to improve process robustness. It is desirable for some applications that the diffracted order alignment information in the field 710 (FIG. 5) and the intensity information of the same polarization state of the diffracted order as shown in fields 720, 730, 740, and 750 be projected on the same array detector. As mentioned, projecting information pertaining to the same polarization state may be accomplished by the placement of the HWP 550 or its equivalent in the arm 535. If an element such as the HWP 550 were not placed in the arm 535 then the image in field 710 on the array detectors 610 and 640 would come from a polarization state that is orthogonal to the polarization state of the displayed intensity information. This may be suitable for some applications. There are, however, arrangements in which this would not be preferred because the orthogonal polarization states can have uncorrelated dynamic range differences between two different types of patterns.

All of the folding optics, including mirrors 540, 680, and 650 and folding optics 600 and 630 are optionally provided to allow a more compact arrangement. Depending on the design considerations of a particular implementation, more or fewer such folding optics may be used. In addition, either or both of the array detectors 610 and 640 may be rotated along the z-axis (with the plane of the figure being the xy plane) to provide better frame filling on the array detector.

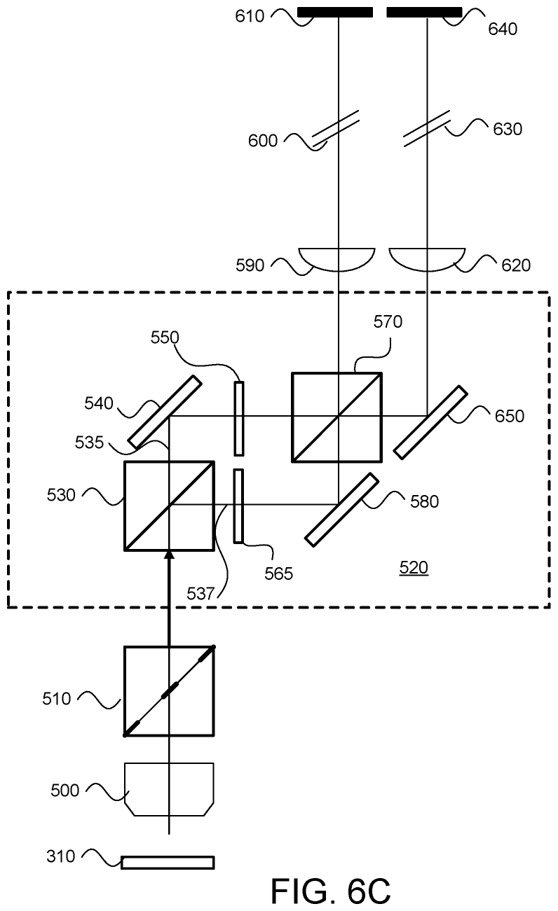

The above embodiments use a segmented wedge to create the spatial separation of the images in the pupil. Use of a segmented wedge provides the advantage that a wedge typically introduces only a small amount of dispersion. One possible implementation of such a segmented wedge is shown in FIG. 8A. As shown, the segmented optical wedge 1100 is made up of four identical segments 1110 arranged symmetrically to divide the pupil into four separate regions. Such a segmented optical wedge 1100 may be fabricated, for example, by gluing the four segments together. Application of the principles elucidated herein is not limited to systems which use four segments or four identical segments and can be applied as well to systems using a different number and/or orientation and/or shape of segments to, for example, capture separate higher orders.

For some embodiments the segments are of the same size and shape and are homogeneously distributed over the pupil. It will be appreciated that this may not be necessary for some applications.

In the above description the optical wedges used in the exemplary embodiments are transmissive. It will be appreciated that reflective optical wedges could be used instead, with appropriate modifications to ray paths and the placement of other components.

While the above examples use polarization filtering to create separate channels, it will be appreciated that channels can also be created using color filtering.

Another advantage of the exemplary embodiments described above is that they can be implemented using a relatively smaller number of demultiplexer modules.

As another alternative to the use of a combination of an optical wedge and lens, it will be appreciated that a segmented lens array may be used. FIG. 8B shows a segmented lens array 1150 implemented as a 2 x 2 lens array such as may be used as a partitioned aperture wavefront (PAW) imaging lens. In the example shown the segmented lens array 1150 is a quatrefoil lens made up of four lenses 1160 that are cut off-axis and glued together. The images are obtained for each quadrant from the portion 1170 of the lens 1160 close to its intersection with the other lenses.

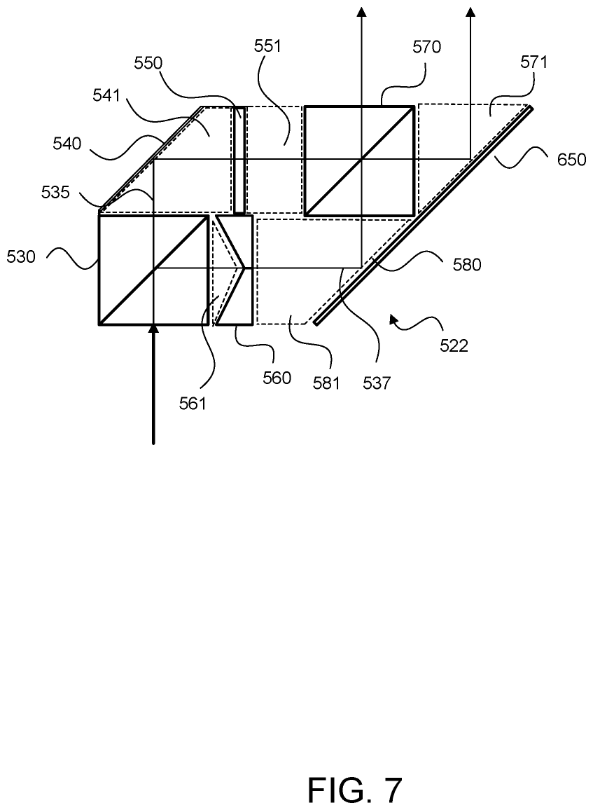

FIG. 5A shows one possible arrangement for fields for the combined display 700. As mentioned, the combined display 700 includes a central field 710 which includes the collection of fringe patterns 350 from FIG. 2B. The surrounding fields 720, 730, 740, and 750 include individual polarization intensity information. FIG. 9 is a graphical representation of the arrangement of the five fields 710, 720, 730, 740, and 750 of FIG. 5. The center field 710 is positioned at or near the center of the combined display 700 with the intensity fields 720, 730, 740, and 750 being disposed at the corners of a square centered around the center field 710. This arrangement is created by operation of the optical wedge, for example, the optical wedge 560 of the arrangement of FIG. 4, which displaces the peripheral fields with respect to the center of the combined image 710. Thus, to displace field 750 from the center of the combined image 700 in the direction of the arrow A, the optical wedge has a wedge angle which is proportional by a proportionality constant k to the required image shift with the image shift being at least two times the radius r of the field. The proportionality constant k will in general depend in a known manner on the focal length of the lens used and the optical properties of the wedge such as its refractive index.

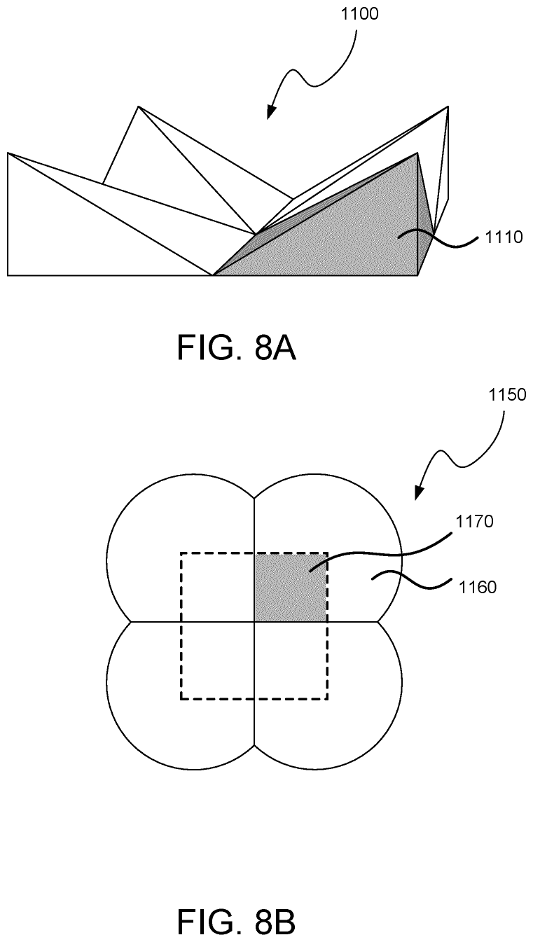

The field arrangement of FIG. 9 is one of many possible such arrangements. For some implementations other arrangements may provide advantages. For example, the arrangement shown in FIG. 10 is potentially more compact than the arrangement shown in FIG. 9. In the arrangement shown in FIG. 10 the net displacement shown by the dashed arrow may be caused by using a first optical wedge having a wedge angle A to cause a first displacement A and a second optical wedge having a wedge angle E to cause a second displacement E. In the arrangement of FIG. 10 in general the image shift should be greater than k*√2r where k is the proportionality constant mentioned above and r is the field radius.

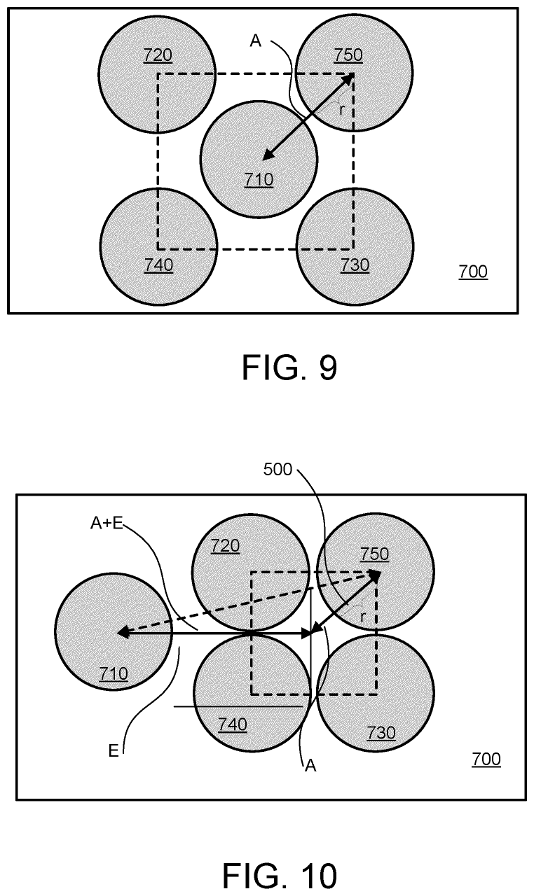

FIG. 11 shows another arrangement in which the centers of the peripheral fields 720, 730, 740, and 750 are not located on the vertices of a square but instead located on the vertices of a rectangle. This combined display 700 is thus compressed in the vertical dimension of the figure. Again, this is more compact and permits greater magnification of the fields.

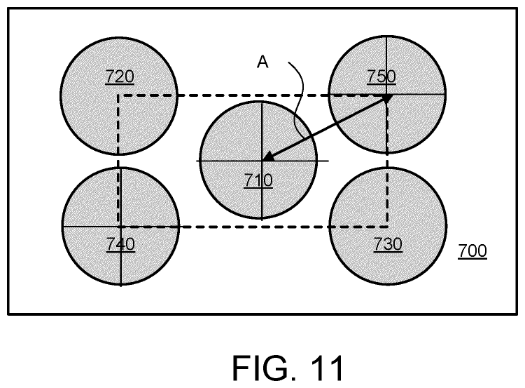

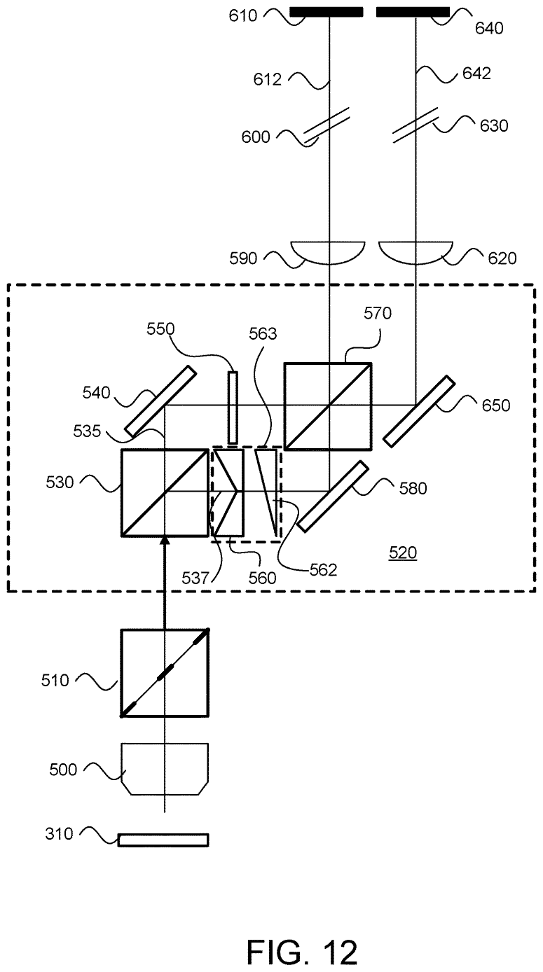

There are several different arrangements of optical elements that may be used to obtain the field arrangements shown in FIGS. 9, 10, and 11. FIG. 12 shows one such arrangement in which an additional optical wedge 562 is placed in one of the arms of the arrangement to introduce the additional field image displacement described above. FIG. 13A is a closeup view of the optical wedge 560 and the additional optical wedge 562 in a combination 563. The same displacement can be obtained by using a single optical wedge 564 as shown in FIG. 13B which is a combination of which 562 and 560. In the embodiment shown in FIG. 13B the angle 0 of the face of the bottom portion of the optical wedge 564 with the waist of the combined optical wedge 564 is such that the face extends to the left in the figure, i.e., such that the angle θ has a sign that is opposed to (the opposite of) the sign of the angle δ. As shown in FIG. 13C it is also possible to have an arrangement 565 in which the angle θ of the face of the bottom portion of the optical wedge 566 is such that the face extends to the right in the figure i.e., such that the angle θ has a sign that is the same as the sign of the angle δ.

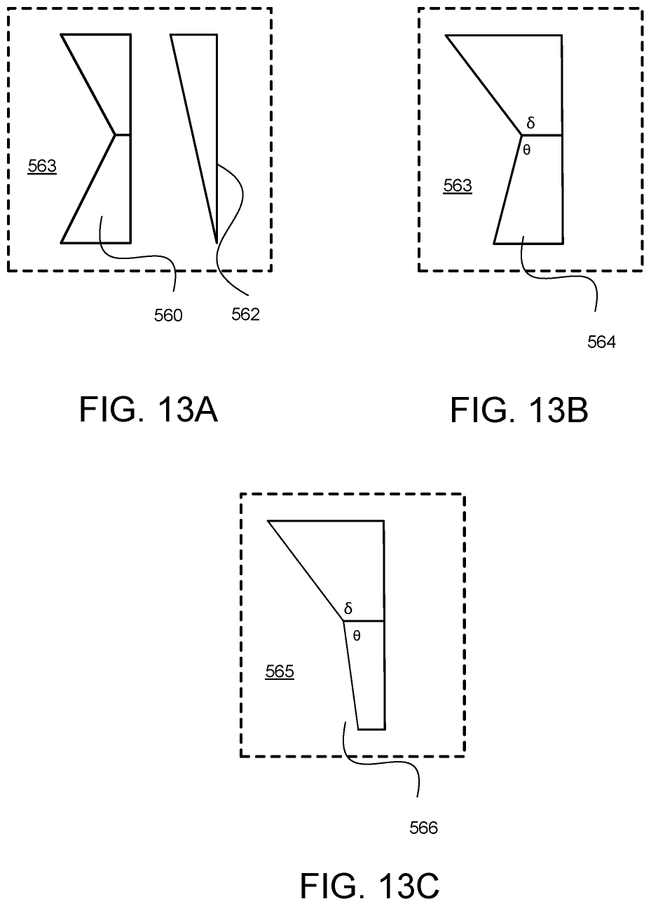

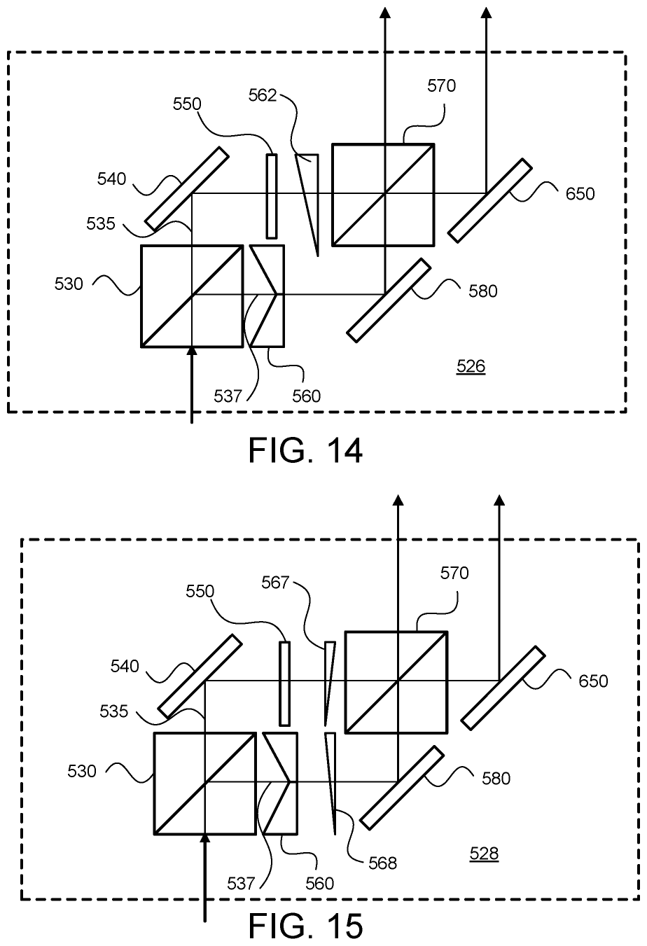

Also, the relative positioning of the fields to the combined image 700 can be achieved by placing the optical wedge 562 in the other arm of the arrangement. This is shown in FIG. 14. It is also possible to achieve this effect by placing a first optical wedge with a first wedge angle in one of the arms and placing a second optical wedge with a second wedge angle in the other arm. The angles are selected to displace the beams in each arm in opposite directions and with magnitudes that sum to the net desired displacement. An example of such an arrangement is shown in FIG. 15. Thus, in the embodiment of FIG. 15, each optical wedge 567 and 568 creates half the total displacement with the wedge angle of the optical wedge 568 each displacing their respective beam by half the total net displacement in opposed directions.

According to another aspect of an embodiment, instead of using or modifying one or more optical wedges to effect the desired image displacement it is also to tilt one or more of the mirrors 540 or 580 or the beam splitters 530 or 570 to achieve the desired displacement of the fields in the combined display 700. Employing such means to achieve the displacement has the advantage of requiring fewer optical elements. Also, tilting mirrors to displace images may have fewer dispersive (achromatic) effects compared to effects caused by adding a transmissive wedge.

Also, according to another aspect of an embodiment, in some arrangements the wedge angles of optical wedges A, B, C, and D could be decreased by a factor of √2 with respect to the arrangement of FIGS. 5A and 9.

Embodiments are described above which are examples of configurations having two optical paths in which a full image comes from one path and one or more, e.g., four, partial images (corresponding to quarter pupils) come from the other path. One of ordinary skill in the art will readily appreciate, however, that in principle alternate configurations are possible. For example, as mentioned, in one embodiment the first path, which may be configured as above, may convey a conventional bright-field image and the other path may convey a “dark-field imaging mode” image. In such an embodiment a partial pupil block may be placed in the along with an image separation element (e.g., a wedge or tilted mirror or tilted beam splitter) to separate the images on the camera.

As another example, one of the paths could implement a “phase contrast imaging mode.” Such an arrangement would use a phase plate in part of the pupil, that shifts the phase in that part of the pupil with respect to the rest of the pupil.

As yet another example, there may be an arrangement in which a focused image comes from one path and a defocused image comes from the other path. This could be achieved by, for example, adding a weak lens in the second path. Such an arrangement would essentially enable retrieving both the phase and amplitude of the light from a single image (at least if spatially coherent light is used).

The above description includes examples of multiple embodiments. It is, of course, not possible to describe every conceivable combination of components or methodologies for purposes of describing the aforementioned embodiments, but one of ordinary skill in the art may recognize that many further combinations and permutations of various embodiments are possible. Accordingly, the described embodiments are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is construed when employed as a transitional word in a claim. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The implementations can be further described using the following clauses.

1. A metrology device arranged to receive radiation that has interacted with a pattern on a substrate, the metrology device comprising:
an optical module arranged to receive at least some of the radiation and adapted to split the radiation into first path radiation travelling in a first arm and second path radiation travelling in a second arm, one of the first arm and the second arm comprising a polarization component adapted to rotate a polarization of a corresponding one of the first path radiation and second path radiation, and the second arm comprising a second arm component adapted to spatially separate the second path radiation,
the optical module further including a polarizing beam splitter arranged to receive the first path radiation from the first arm and the second path radiation from the second arm and to split the first path radiation into first channel first path radiation and second channel first path radiation and split the separated second path radiation into first channel second path radiation and second channel second path radiation and to cause the first channel first path radiation and the first channel second path radiation to co-propagate as combined first channel radiation and to cause the second channel first path radiation and the second channel second path radiation to co-propagate as combined second channel radiation.

2. The metrology device of clause 1 wherein the metrology device is an alignment sensor.

3. The metrology device of clause 1 wherein the metrology device is an overlay sensor.

4. The metrology device of clause 1 wherein the second arm component adapted to spatially separate the second path radiation is configurable.

5. The metrology device of clause 1 wherein the second arm component adapted to spatially separate the second path radiation comprises a rotatable wedge.

6. The metrology device of clause 1 further comprising:
a first lens arranged to focus the combined first channel radiation;

a first array detector arranged at a focal plane of the first lens;
a second lens arranged to focus the combined second channel radiation; and
a second array detector arranged at a focal plane of the second lens.

7. The metrology device of clause 6 wherein the first array detector comprises a first camera and the second array detector comprises a second camera.

8. The metrology device of clause 6 wherein the first array detector has a first optical axis and
wherein the first array detector is rotatable with respect to the first optical axis to improve filling of the first array detector by the first channel radiation.

9. The metrology device of clause 1 wherein the polarization component comprises a half-wave plate.

10. The metrology device of clause 1 wherein the first arm comprises the polarization component adapted to rotate a polarization of the first path radiation.

11. The metrology device of clause 10 wherein the polarization component comprises a half-wave plate.

12. The metrology device of clause 1 wherein the second arm component comprises a segmented optical wedge arranged to spatially separate the second path radiation.

13. The metrology device of clause 12 wherein the segmented optical wedge is transmissive.

14. The metrology device of clause 12 wherein the segmented optical wedge is reflective.

15. The metrology device of clause 1 wherein the second arm component comprises a partitioned aperture wavefront imaging lens.

16. The metrology device of clause 1 further comprising
at least one camera arranged to receive the combined first channel radiation; and
a display arranged to show a first image based on the combined first channel radiation.

17. The metrology device of clause 16 wherein the second arm component is arranged so that the first image comprises a central image and four displaced images arranged around the first image.

18. The metrology device of clause 16 wherein the first image comprises a central image and four displaced images and wherein the second arm comprises an additional second arm component arranged to laterally displace the displaced four images such that the display shows the displaced four images laterally displaced from the central image.

19. The metrology device of clause 1 wherein the second arm component comprises a tiltable beam splitter.

20. The metrology device of clause 1 wherein the second arm component comprises a tiltable folding mirror.

21. A metrology device configured to collect radiation that has interacted with a pattern on a substrate, the metrology device comprising:
an optical module arranged to receive at least some of the radiation and adapted to split the radiation into first path radiation travelling in a first arm and second path radiation travelling in a second arm, the first arm including a half-wave plate adapted to rotate a polarization of the first path radiation, the second arm including a segmented optical wedge arranged to spatially separate the second path radiation, and
the optical module further including a polarizing beam splitter arranged to receive the first path radiation from the first arm and the second path radiation from the second arm and to split the first path radiation into first channel first path radiation and a second channel first path radiation and split the separated second path radiation into first channel second path radiation and a second channel second path radiation and to cause the first channel first path radiation and the first channel second path radiation to co-propagate as combined first channel radiation and to cause the second channel first path radiation and the second channel second path radiation to co-propagate as combined second channel radiation;
a first lens arranged to receive and focus the combined first channel radiation;
a first array detector arranged at a focal plane of the first lens;
a second lens arranged to receive and focus the combined second channel radiation; and
a second array detector arranged at a focal plane of the second lens.

22. The metrology device of clause 21 wherein the metrology device is an alignment sensor.

23. The metrology device of clause 21 wherein the metrology device is an overlay sensor.

24. The metrology device of clause 21 wherein the first array detector comprises a first camera and the second array detector comprises a second camera.

25. The metrology device of clause 21 wherein the first array detector has a first optical axis and wherein the first array detector is rotatable with respect to the first optical axis to improve filling of the first channel radiation on the first array detector.

26. The metrology device of clause 21 wherein the segmented optical wedge is rotatable.

27. The metrology device of clause 21 further comprising
at least one camera arranged to receive the first path radiation and the spatially separated second path radiation and
a display arranged to show simultaneously a first image based on the first path radiation and at least one image based on the spatially separated the second path radiation.

28. The metrology device of clause 27 wherein the second arm component is arranged so that the display simultaneously shows the first image in a central portion and wherein the at least one image comprises four images arranged around the first image.

29. The metrology device of clause 27 wherein the at least one image comprises four images and wherein the second arm comprises an additional second arm component arranged to laterally shift the four images such that the display shows the four images laterally displaced from the first image.

30. The metrology device of clause 21 wherein the second arm component comprises a tiltable beam splitter.

31. The metrology device of clause 21 wherein the second arm component comprises a tiltable folding mirror.

32. An optical module comprising:
a first arm comprising a half-wave plate;
a second arm comprising a segmented optical wedge;
a neutral beam splitter arranged to split a beam of incoming radiation into a first part travelling in the first arm and a second part travelling in the second arm; and
a polarizing beam splitter arranged to receive the first part after the first part has travelled the first arm and the second part after the second part has travelled the second arm.

33. The optical module of clause 32 wherein the half-wave plate rotates a polarization of the first part by ninety degrees.

34. The optical module of clause 32 wherein the segmented optical wedge separates the second part into a plurality of spatially separated components.

35. The optical module of clause 32 wherein the polarizing beam splitter causes a first portion of the first part to co-propagate with a first portion of the second part.

36. The optical module of clause 35 wherein the polarizing beam splitter causes a second portion of the first part to co-propagate with a second portion of the second part.

37. The optical module of clause 32 wherein the optical module is an alignment sensor.

38. The optical module of clause 32 wherein the optical module is an overlay sensor.

39. The optical module of clause 32 wherein the segmented optical wedge is rotatable.

40. An optical module comprising:
a first optical component comprising a neutral beam splitter arranged to split a beam of incoming radiation into a first part travelling in a first arm and a second part travelling in a second arm, the first arm comprising a second optical component comprising a half-wave plate, and
the second arm comprising a third optical component comprising a segmented optical wedge; and a fourth optical component comprising a polarizing beam splitter arranged to receive the first part after the first part has travelled the first arm and the second part after the second part has travelled the second arm,
and further comprising
a first transparent element attached to and connecting the first optical component and the second optical component,
a second transparent element attached to and connecting the second optical component and the fourth optical component,
a third transparent element attached to and connecting the first optical component and the third optical component, and
a fourth transparent element attached to and connecting the third optical component and the fourth optical component,
such that the optical module is configured as a monolithic block.

41. The optical module of clause 40 wherein the half-wave plate rotates a polarization of the first part by ninety degrees.

42. The optical module of clause 40 wherein the segmented optical wedge separates the second part into a plurality of spatially separated components.

43. The optical module of clause 40 wherein the polarizing beam splitter causes a first portion of the first part to co-propagate with a first portion of the second part.

44. The optical module of clause 43 wherein the polarizing beam splitter causes a second portion of the first part to co-propagate with a second portion of the second part.

45. The optical module of clause 40 wherein the optical module is an alignment sensor.

46. The optical module of clause 40 wherein the optical module is an overlay sensor.

47. The optical module of clause 40 wherein the segmented optical wedge is rotatable.

48. A metrology method comprising:
gathering radiation that has interacted with a pattern on a substrate;
splitting at least part of the radiation into first path radiation and second path radiation,
rotating a polarization of one of the first path radiation and the second path radiation, and
splitting the first path radiation into first channel first path radiation and second channel first path radiation and splitting the separated second path radiation into first channel second path radiation and second channel second path radiation and to cause the first channel first path radiation and the first channel second path radiation to co-propagate as combined first channel radiation and to cause the second channel first path radiation and the second channel second path radiation to co-propagate as combined second channel radiation.

49. The metrology method of clause 48 further comprising focusing the combined first channel radiation on a first array detector and focusing the combined second channel radiation on a second array detector.

50. A metrology device configured to collect radiation that has interacted with a pattern on a substrate, the metrology device comprising:
an optical module arranged to receive at least some of the radiation and adapted to split the radiation into a first radiation portion propagating in a first arm and a second radiation portion propagating in the second arm, the first arm having a first optical configuration and the second arm having a second optical configuration different from the first optical configuration; and
an optical element arranged to receive the first radiation portion after the first radiation portion has traversed the first arm and the second radiation portion after the second radiation portion has traversed the second arm and to generate a composite image of the first radiation portion and the second radiation portion.

51. The metrology device of clause 50 wherein one of the first arm and the second arm comprises a polarization component adapted to rotate a polarization of the first path radiation and wherein the second arm comprises a second arm module adapted to spatially separate the second radiation portion into spatially separated components.

The above described implementations and other implementations are within the scope of the following claims.

1. A metrology device arranged to receive radiation that has interacted with a pattern on a substrate, the metrology device comprising:
an optical module arranged to receive at least some of the radiation and adapted to split the radiation into first path radiation travelling in a first arm and second path radiation travelling in a second arm,
one of the first arm and the second arm comprising a polarization component adapted to rotate a polarization of a corresponding one of the first path radiation and second path radiation, and
the second arm comprising a second arm component adapted to spatially separate the second path radiation,
the optical module further including a polarizing beam splitter arranged to receive the first path radiation from the first arm and the second path radiation from the second arm and to split the first path radiation into first channel first path radiation and second channel first path radiation and split the separated second path radiation into first channel second path radiation and second channel second path radiation and to cause the first channel first path radiation and the first channel second path radiation to co-propagate as combined first channel radiation and to cause the second channel first path radiation and the second channel second path radiation to co-propagate as combined second channel radiation.

2. The metrology device of claim 1 wherein the metrology device is an alignment sensor.

3. The metrology device of claim 1 wherein the metrology device is an overlay sensor.

4. The metrology device of claim 1 wherein the second arm component adapted to spatially separate the second path radiation is configurable.

5. The metrology device of claim 1 wherein the second arm component adapted to spatially separate the second path radiation comprises a rotatable wedge.

6. The metrology device of claim 1 further comprising:
a first lens arranged to focus the combined first channel radiation;
a first array detector arranged at a focal plane of the first lens;
a second lens arranged to focus the combined second channel radiation; and
a second array detector arranged at a focal plane of the second lens.

7. The metrology device of claim 6 wherein the first array detector comprises a first camera and the second array detector comprises a second camera.

8. The metrology device of claim 6 wherein the first array detector has a first optical axis and wherein the first array detector is rotatable with respect to the first optical axis to improve filling of the first array detector by the first channel radiation.

9. The metrology device of claim 1 wherein the polarization component comprises a half-wave plate.

10. The metrology device of claim 1 wherein the first arm comprises the polarization component adapted to rotate a polarization of the first path radiation.

11. The metrology device of claim 10 wherein the polarization component comprises a half-wave plate.

12. The metrology device of claim 1 wherein the second arm component comprises a segmented optical wedge arranged to spatially separate the second path radiation.

13. The metrology device of claim 12 wherein the segmented optical wedge is transmissive.

14. The metrology device of claim 12 wherein the segmented optical wedge is reflective.

15. The metrology device of claim 1 wherein the second arm component comprises a partitioned aperture wavefront imaging lens.
